(19) United States
(12) Patent Application Publication
(10) Pub. No.: US 2011/0080382 A1
(43) Pub. Date: Apr. 7, 2011

(54) ELECTRONIC DEVICE, DISPLAY DEVICE AND METHOD OF CONTROLLING THE DISPLAY DEVICE

(76) Inventor: Kyunghoi Koo, Suwon-si (KR)

(21) Appl. No.: 12/859,483

(22) Filed: Aug. 19, 2010

(30) Foreign Application Priority Data
Oct. 6, 2009 (KR) 10-2009-0094741

(51) Int. Cl. G06F 3/038; H03L 7/00; H03B 1/00

(52) U.S. Cl. 345/204; 327/141; 327/108

(57) ABSTRACT

A display device includes a plurality of source drivers and a timing controller. The timing controller generates a plurality of output clock signals corresponding to respective source drivers and provides a data signal to each of the plurality of source drivers in synchronization with the plurality of output clock signals. The output clock signals have a different phase relative to the output clock signals corresponding to adjacent source drivers among the plurality of source drivers.

### BACKGROUND

1. Field

The present disclosure herein relates to an electronic device such as a display device.

2. Description of the Related Art

Since a differential signal transmission is advantageous in aspects of electromagnetic interference (EMI) and electromagnetic compatibility (EMC), compared with a single-ended signal transmission, the differential signal transmission is increasingly used in data interface of a storage application, a multi-bit data bus of a DRAM, a module interface of a mobile apparatus, etc. as well as a variety of digital display devices such as a plasma display panel (PDP) driver circuitry, a liquid crystal display (LCD) driver circuitry, etc. The differential signal transmission uses two physical signal lines, i.e., a signal line for transmitting a positive (+) signal, and a signal line for transmitting a negative (−) signal, so as to transmit 1-bit data. Therefore, the differential signal transmission is advantageous in aspects of EMI/EMC, compared with the single-ended transmission, and guarantee uniform return path. Also, in the differential signal transmission, since signal lines transmitting a differential signal pair are designed to be disposed adjacent to each other, it is regarded that noise is cancelled in a far-field and thus the differential signal transmission has a strong characteristic with respect to an external noise such as crosstalk.

However, in the case where data signals are transmitted at the same time through a plurality of data signal lines arranged adjacent to each other, the differential signal transmission has a limitation that the EMI characteristic is deteriorated.

### SUMMARY

The present disclosure provides a display device and a method of controlling the same that can minimize interference between adjacent data signal lines and prevent EMI characteristic from being lowered.

Embodiments of the inventive concept provide display devices including a plurality of source drivers, and a timing controller generating a plurality of output clock signals respectively corresponding to the plurality of source drivers and providing a data signal to each of the plurality of source drivers in synchronization with the plurality of output clock signals. The output clock signals have a different phase relative to the output clock signals corresponding to adjacent source drivers among the plurality of source drivers.

In some embodiments, the timing controller may further provide a clock signal to the plurality of source drivers, and each of the plurality of source drivers may recover the data signal provided from the timing controller in synchronization with the clock signal.

In other embodiments, the data signal and the clock signal provided from the timing controller to the plurality of source drivers may be differential signals, respectively.

In still other embodiments, the timing controller may include a clock generator generating a plurality of internal clock signals having different phases, and a plurality of data output circuitries corresponding to respective source drivers of the plurality of source drivers, the data output circuitries selecting any one of the plurality of internal clock signals as the output clock signal, and outputting the data signal to be provided to the corresponding source driver in synchronization with the selected output clock signal.

In even other embodiments, each of the plurality of data output circuitries may include a selector selecting any one of the plurality of internal clock signals as the output clock signal in response to a select signal, a parallel-to-serial converter converting a parallel data signal inputted from an outside to a serial data signal and outputting the converted serial data signal as the data signal in synchronization with the output clock signal, and a differential driver converting the data signal to a differential signal and providing the converted differential signal to the corresponding source driver.

In yet other embodiments, the select signal may enable the selectors in the respective data output circuitries corresponding to adjacent source drivers to select internal clock signals having predetermined phase differences from the plurality of internal clock signals.

In further embodiments, the select signal may enable the selectors in the respective data output circuitries corresponding to at least two adjacent source drivers to select internal clock signals having complementary phases from the plurality of internal clock signals.

In still further embodiments, the plurality of source drivers may be grouped into a first group of source drivers and a second group of source drivers according to an arrangement of the plurality of source drivers. The timing controller may provide a first clock signal to the first group of source drivers and a second clock signal to the second group of source drivers, the first clock signal being different from the second clock signal.

In even further embodiments of the inventive concept, display devices include a plurality of source drivers, and a timing controller providing a data signal to each of the plurality of source drivers. The timing controller includes a clock generator generating a plurality of internal clock signals having different phases, and a plurality of data output circuitries corresponding to respective source drivers, the data output circuitries selecting any one of the plurality of internal clock signals, and outputting the data signal to be provided to the corresponding source driver in synchronization with the selected internal clock signal.

In yet further embodiments, each of the plurality of data output circuitries may include a selector selecting any one of the plurality of internal clock signals as an output clock signal in response to a select signal, a parallel-to-serial converter converting a parallel data signal inputted from an outside to a serial data signal and outputting the converted serial data signal as the data signal in synchronization with the output clock signal, and a differential driver converting the data signal to a differential signal and providing the converted differential signal to the corresponding source driver.

In other embodiments, the select signal may enable the selectors in the respective data output circuitries corresponding to adjacent source drivers to select internal clock signals having difference phases from the plurality of internal clock signals.

In still other embodiments of the inventive concept, electronic devices include a plurality of first semiconductor chips, a second semiconductor chip generating a plurality of output clock signals corresponding to respective first semiconductor chips and providing a data signal to each of the plurality of first semiconductor chips in synchronization with the plurality of output clock signals, and a printed circuit board having a plurality of signal lines arranged thereon, the plurality of signal lines transmitting the data signals provided from the second semiconductor chip to the plurality of first semiconductor chips. The output clock signals have a different phase relative to the output clock signals corresponding to adjacent first semiconductor chips among the plurality of first semiconductor chips.

In even other embodiments, the second semiconductor chip may further provide a clock signal to the plurality of first semiconductor chips, and each of the plurality of first semiconductor chips may recover the data signal provided from the second semiconductor chip in synchronization with the clock signal.

In yet other embodiments, the second semiconductor chip may include a clock generator generating a plurality of internal clock signals having different phases, and a plurality of data output circuitries respectively corresponding to the plurality of source drivers, selecting any one of the plurality of internal clock signals as the output clock signal, and outputting the data signal to be provided to the corresponding source driver in synchronization with the selected output clock signal.

In further embodiments of the inventive concept, control methods for generating a data signal to be provided to a source driver include generating a plurality of internal clock signals having different phases, selecting any one of the plurality of internal clock signals as an output clock signal, converting a received parallel data signal to a serial data signal, outputting the serial data signal as a data signal in synchronization with the selected output clock signal, and providing the data signal to the source driver.

In still further embodiments, the above control method may further include converting the data signal to a differential signal, and the differential signal may be provided to the source driver.

In even further embodiments of the inventive concept, methods of controlling a display device for generating a data signal to be provided to a plurality of source drivers include generating a plurality of internal clock signals having different phases, selecting each of the plurality of internal clock signals as output clock signals corresponding to respective source drivers of the plurality of source drivers, converting parallel data signals corresponding to respective source drivers of the plurality of source drivers to serial data signals, outputting the serial data signals corresponding to respective source drivers of the plurality of source drivers as data signals in synchronization with the output clock signals corresponding to respective source drivers of the plurality of source drivers, and providing the data signals to the plurality of corresponding source drivers.

In yet further embodiments, the selecting of each of the plurality of internal clock signals as the output clock signals includes matching the plurality of internal clock signals with the corresponding source drivers, such that the output clock signals corresponding to adjacent source drivers have different phases.

In other embodiments, the selecting of each of the plurality of internal clock signals as the output clock signal includes matching the plurality of internal clock signals with the corresponding source drivers, such that the output clock signals corresponding to at least two adjacent source drivers have complementary phases.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a perspective view of a display unit according to an exemplary embodiment of the inventive concept;

FIG. 2 illustrates a schematic view illustrating the connection relation between a timing controller and source drive chips;

FIG. 3 illustrates a timing diagram of the clock signals provided from the timing controller shown in FIG. 2 to the source drive chips;

FIG. 4 illustrates a block diagram illustrating a constitution of a display device according to an embodiment of the inventive concept;

FIG. 5 illustrates a timing diagram exemplarily illustrating the output clock signals generated in the timing controller shown in FIG. 4;

FIG. 6 illustrates a timing diagram of the output clock signals generated in the timing controller shown in FIG. 4 according to another embodiment of the inventive concept;

FIG. 7 illustrates a block diagram showing a concrete constitution of the timing controller shown in FIG. 4;

FIG. 8 illustrates a flow diagram illustrating a method of controlling the timing controller shown in FIG. 4 according to an embodiment of the inventive concept; and

FIG. 9 illustrates a graph illustrating a decrease in current consumed in a display device according to an embodiment of the inventive concept.

### DETAILED DESCRIPTION

Korean Patent Application No. 10-2009-0094741, filed on Oct. 6, 2009, in the Korean Intellectual Property Office, and entitled: “Electronic Device, Display Device and Method of Controlling the Display Device,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout

Exemplary embodiments of the inventive concept will be described below in more detail with reference to the accompanying drawings.

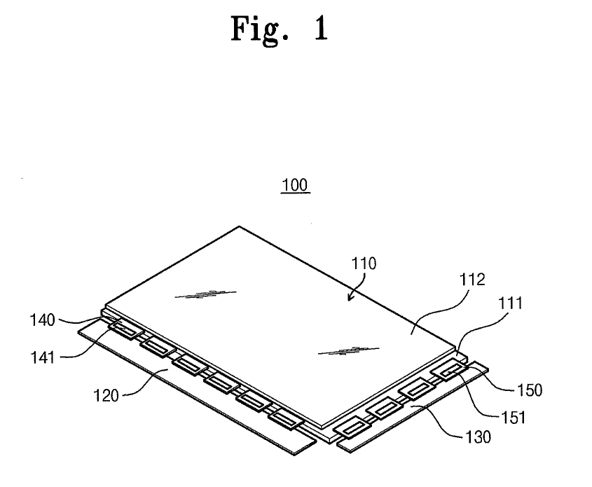

FIG. 1 is a perspective view of a display unit according to an exemplary embodiment of the inventive concept.

Although a liquid crystal display device is shown in FIG. 1 and described as an example of a display device, the display device may be a device such as a light emitting diode (LED), a plasma display panel (PDP), an organic light emitting diode (OLED) or the like.

Referring to FIG. 1, a liquid crystal display device 100 according to the inventive concept includes a liquid crystal display panel 110, a source printed circuit board (PCB) 120, and a gate printed circuit board 130. The liquid crystal display panel 110 includes a thin film transistor (TFT) substrate 111, a color filter substrate 112 coupled with the TFT substrate 111 while facing the TFT substrate 111, and a liquid crystal layer injected between the TFT substrate 111 and the color filter substrate 112.

The TFT substrate 111 is a transparent glass substrate on which a plurality of TFTs as switching elements are arranged in a matrix configuration. A source line is connected to source terminals of the TFTs, and a gate line is connected to gate terminals of the TFTs. Also, a common electrode made of a transparent conductive material is connected to drain terminals of the TFTs.

In the liquid crystal display device 100 having the above-described constitution, when a power is applied to the gate terminals of the TFTs to turn on the TFTs, an electric field is formed between pixel electrodes and the common electrode. Due to the formed electric field, an arrangement of liquid crystal molecules constituting the liquid crystal layer disposed between the TFT substrate 111 and the color filter substrate 112 is changed and transmittance of light supplied from a light source is also changed to obtain an image having a desired gray scale.

The source and gate PCBs 120, 130 are respectively connected to the liquid crystal display panel 110 through a source drive circuit film 140 and a gate drive circuit film 150, and provide an image signal and scan signals for driving the liquid crystal display panel 110, respectively. The source and gate drive circuit films 140, 150 are configured, as one example, by a tape carrier package (TCP) or a chip on film (COF). The source and gate drive circuit films 140, 150 further include respective source and gate drive chips 141, 151 controlling a timing of a drive signal so as to apply the drive signal provided from the source PCB 120 to the liquid crystal display panel 110 at a proper timing.

The numbers of the source drive chips 141 and the gate drive chips 151 provided in the liquid crystal display device 100 are determined by the resolution of the liquid crystal display panel, the number of channels of the drive chip, the operating frequency, and etc.

Although not shown in FIG. 1, the source drive chips 141 receive data signals and clock signals from an external timing controller and output image signals for driving the liquid crystal display panel 110. The data signals and the clock signals provided from the external timing controller are provided to the source drive chips 141 through data signal lines and data signal lines arranged on the source PCB 120.

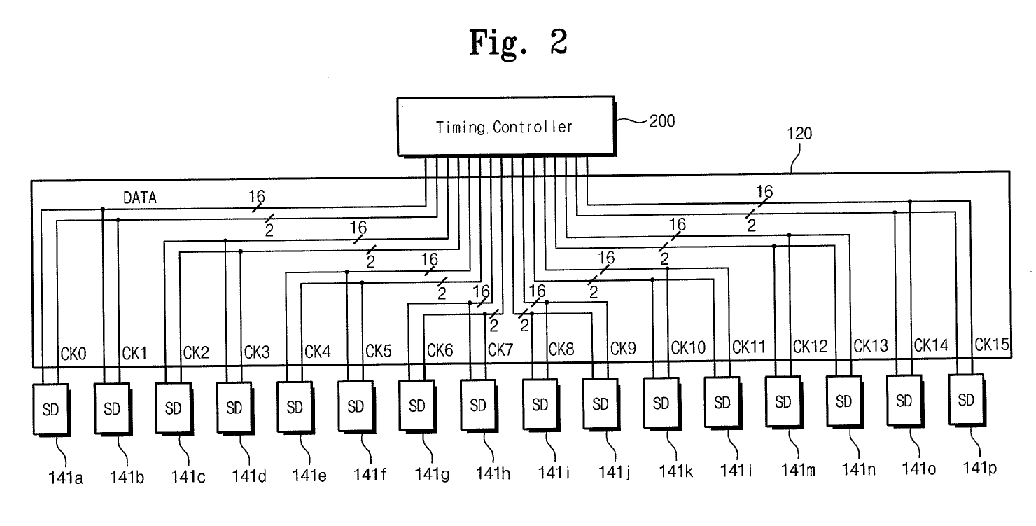

FIG. 2 is a schematic view illustrating the connection relation between a timing controller and source drive chips.

Referring to FIG. 2, the timing controller 200 transmits clock signals CK0-CK15 corresponding to a data signal DATA to the respective source drive chips 141a-141p. The data signal DATA and the clock signals CK0-CK15 provided to the respective source drive chips 141a-141p from the timing controller 200 are differential signals. Signal lines for transmitting the data signal DATA and the clock signals CK0-CK15 from the timing controller 200 to the respective source drive chips 141a-141p are arranged on the source PCB 120.

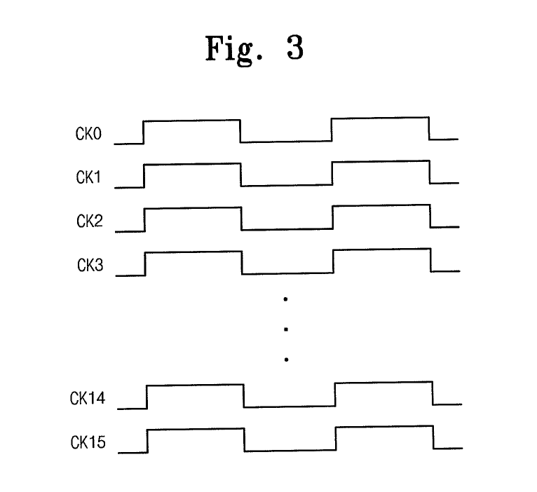

FIG. 3 is a timing diagram of the clock signals provided from the timing controller shown in FIG. 2 to the source drive chips.

Referring to FIG. 3, the clock signals CK0-CK15 provided from the timing controller 200 to the source drive chips 141a-141p all have the same phase. Also, the data signal DATA provided from the timing controller 200 to the source drive chips 141a-141p is synchronized with the clock signals CK0-CK15. Since the data signal is transmitted simultaneously at a right edge or falling edge of the clock signals CK0-CK15, problems such as crosstalk between signal lines, timing skew, signal integrity, and etc., may occur. Accordingly, in designing the timing controller 200, the PCB 120 and the source drive chips 141a-141p, the foregoing problems should be considered. In particular, since the data signals DATA are transmitted at the same timing, electromagnetic interference (EMI) characteristic may be lowered.

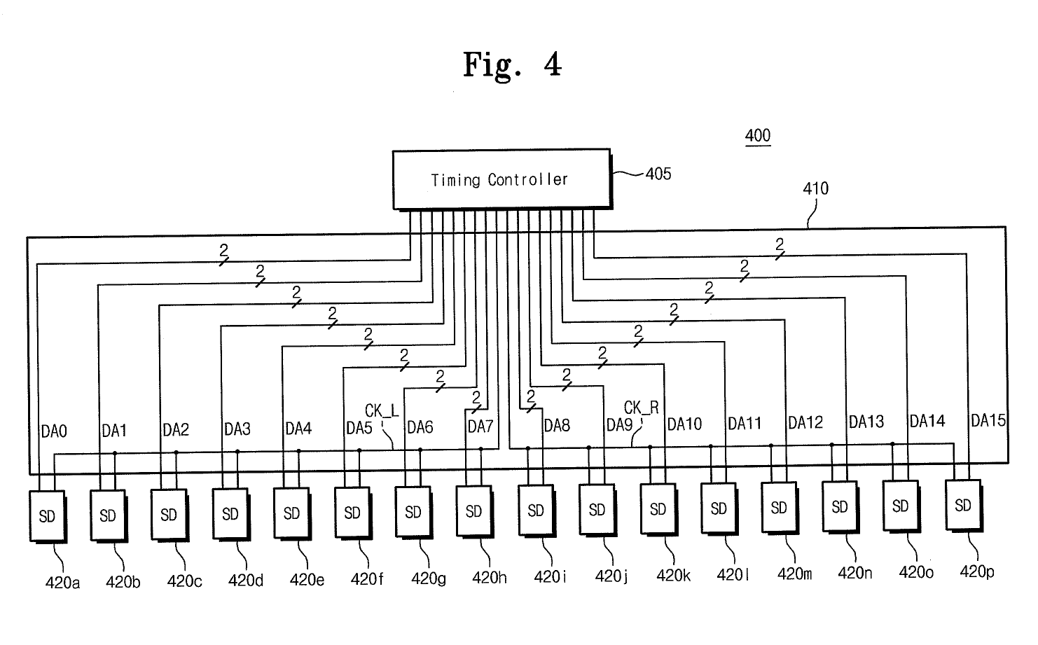

FIG. 4 is a block diagram illustrating a constitution of a display device according to an embodiment of the inventive concept.

Referring to FIG. 4, the display device 400 includes a timing controller 405, a PCB 410, and source drive chips 420a-420p. The timing controller 400 transmits data signals DA0-DA15 and clock signals CK_L, CK_R to the respective source drive chips 420a-420p in synchronization with an image data signal and a synchronous signal provided from a host (not shown). The respective source drive chips 420a-420p output image signals for driving a liquid crystal display panel (not shown) in response to the data signals DA0-DA15 and the clock signals CK_L, CK_R transmitted from the timing controller 405. The data signals DA0-DA15 and the clock signals CK_L, CK_R transmitted from the timing controller 405 are provided to the source drive chips 420a-420p through data signal lines and clock signal lines arranged on the PCB 410. The data signals DA0-DA15 and the clock signals CK_L, CK_R transmitted from the timing controller 405 to the source drive chips 141a-141p are differential signals.

In this embodiment, the source drive chips 420a-420p are divided into two groups, i.e., a first group and a second group. The first group includes the source drive chips 420a-420h, and the second group includes the source drive chips 420i-420p. The first group of source drive chips 420a-420h recover the respective data signals DA0-DA7 inputted in synchronization with the first clock signal CK_L from the timing controller 405. The second group of source drive chips 420i-420p recover the respective data signals DA8-DA15 inputted in synchronization with the second clock signal CK_R from the timing controller 405. Thus, the reason why the source drive chips 420a-420p are divided into two groups and the first clock signal CK_L and the second clock signal CK_R are provided to the respective groups is to minimize influences of noise and attenuation due to an increase in the length of signals lines transmitting the clock signals.

The timing controller 405 generates output clock signals CLK0_OUT-CLK15_OUT corresponding to the source drive chips 420a-420p, and outputs data signals DA0-DA 15 to the source drive chips 420a-420p in synchronization with the generated output clock signals CLK0_OUT-CLK15_OUT.

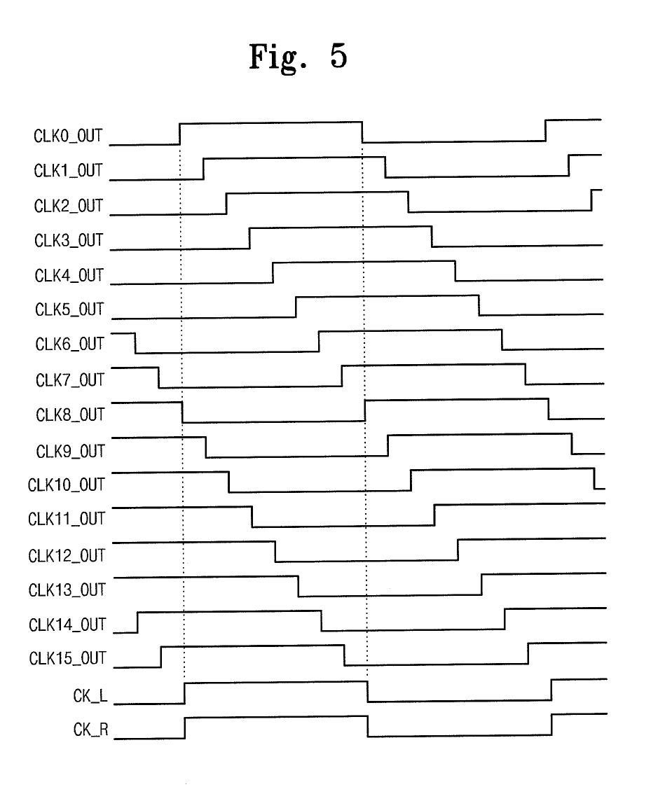

FIG. 5 is a timing diagram exemplarily illustrating the output clock signals generated in the timing controller shown in FIG. 4.

Referring to FIG. 5, the output clock signals CLK0_OUT-CLK15_OUT generated in the timing controller 405 correspond to the source drive chips 420a-420p, respectively. The output clock signals CLK0_OUT-CLK15_OUT are sequentially shifted with a predetermined phase difference, e.g., relative to the output clock signals correspond to adjacent source drive chips. For example, the timing controller 405 outputs the data signal DA0 to the source drive chip 420a at a rising edge of the output clock signal CLK0_OUT, and outputs the data signal DA1 to the source drive chip 420b at a rising edge of the output clock signal CLK1_OUT. The source drive chips 420a-420h recover the data signals DA0-DA7 inputted in synchronization with the first clock signal CK_L, respectively, and the source drive chips 420i-420p recover the data signals DA8-DA15 inputted in synchronization with the second clock signal CK_R, respectively.

According to this embodiment, transmission timings of the data signals DA0-DA7 transmitted to the first group of source drive chips 420a-420h from the timing controller 405 are different from one another, and transmission timings of the data signals DA8-DA15 transmitted to the second group of source drive chips 420i-420p are different from one another. Therefore, the EMI characteristic of the display device shown in FIG. 4 can be enhanced, compared with that of the display device shown in FIG. 2. However, since a phase difference between the output clock signals CLK0_OUT-CLK15_OUT is fixed, it is difficult to control output timings of the data signals DA0-DA15 according to a characteristic of the PCB 410.

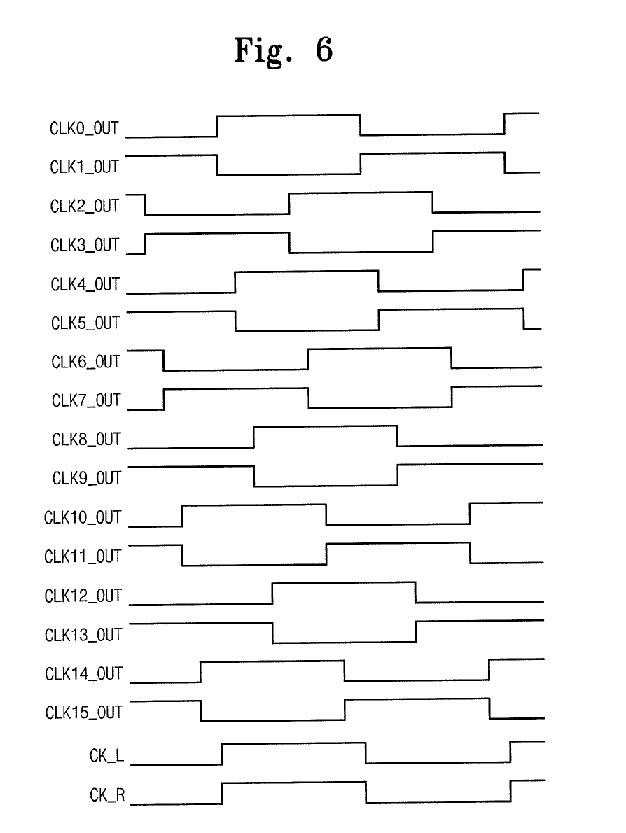

FIG. 6 is a timing diagram of the output clock signals generated in the timing controller shown in FIG. 4 according to another embodiment of the inventive concept.

Referring to FIG. 6, the output clock signals CLK0_OUT-CLK15_OUT generated in the timing controller 405 correspond to the source drive chips 420a-420p, respectively. The output clock signals CLK0_OUT-CLK15_OUT have phases different from one another. In particular, two adjacent clock signals have complementary phases. For example, the output clock signals CLK0_OUT, CLK0_OUT have phases complementary to each other, and the output clock signals CLK2_OUT, CLK3_OUT have phases complementary to each other. As described previously with reference to FIG. 5, the timing controller 405 outputs the data signal DA0 to the source drive chip 420a at a rising edge of the output clock signal CLK0_OUT, and outputs the data signal DA1 to the source drive chip 420b at a rising edge of the output clock signal CLK1_OUT. The source drive chips 420a-420h recover the data signals DA0-DA7 inputted in synchronization with the first clock signal CK_L, respectively, and the source drive chips 420i-420p recover the data signals DA8-DA15 inputted in synchronization with the second clock signal CK_R, respectively. According to this embodiment, since transmission timings of the data signals DA0-DA15 transmitted to the source drive chips 420a-420p from the timing controller 405 are different from one another, the EMI characteristic of the display device shown in FIG. 4 can be enhanced, compared with that of the display device shown in FIG. 2.

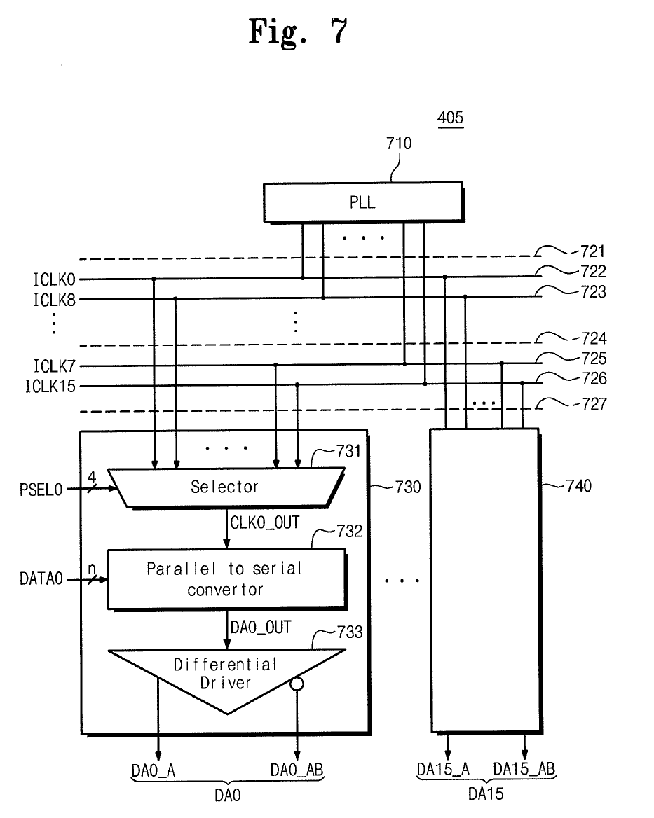

FIG. 7 is a block diagram showing a constitution of the timing controller shown in FIG. 4.

Referring to FIG. 7, the timing controller 405 includes a PLL 710 and output circuitries 730, 740. The PLL 710 generates a plurality of internal clock signals ICLK0-ICLK15. The PLL 710 may further generate the first clock signal CK_L and the second clock signal CK_R shown in FIG. 4. In another example, the first clock signal CK_L and the second clock signal CK_R may be generated by a separate clock generating circuitry. The internal clock signals ICLK0-ICLK15 generated in the PLL 710 are transmitted to the data output circuitries 730, 740 through clock signal lines 722, 723, 725, 726. Shielding lines 721, 724, 727 may be disposed between the clock signal lines 722, 723, 725, 726 so as to decrease interference due to an adjacent clock signal. These shielding lines 721, 724, 727 allow the EMI generated in the timing controller 405 to be decreased.

Although FIG. 7 shows only the two data output circuitries 730, 740 respectively corresponding to the source drive chips SD0, SD 15 shown in FIG. 4, the timing controller 405 includes 16 data output circuitries respectively corresponding to the source drive chips 420a-420p. Each of the data output circuitries corresponding to the source drive chips 420a-420p has the same circuit constitution as those of the source drive chip 420a.

The source drive chip 420a includes a selector 731, a parallel-to-serial converter 732, and a differential driver 733. The selector 731 receives all of the internal clock signals ICLK0-ICLK15 generated in the PLL 710 and selects any one of the internal clock signals ICLK0-ICLK15 as an output clock signal CLK0_OUT in response to a phase select signal PSEL. The parallel-to-serial converter 732 converts a parallel data signal DATA0 provided from a host to a serial data signal DA0_OUT, synchronizes the converted serial data signal DA0_OUT with the output clock signal CLK0_OUT and outputs the synchronized serial data signal DA0_OUT to the differential driver 733. The differential driver 733 converts the serial data signal DA0_OUT to a differential signal pair DA0_A, DA0_AB and outputs the converted differential signal pair DA0_A, DA0-AB. The differential signal pair DA0_A, DA0_AB is a data signal DA0 provided to the source drive chip 420a shown in FIG. 4.

Although not shown in FIG. 7, the phase select signal and the parallel data signal are inputted to each of the data output circuitries corresponding to the source drive chips 420b-420p. The phase select signals inputted to the respective data output circuitries corresponding to the source drive chips 420b-420p are set such that the selectors in the adjacent data output circuitries select internal clock signals having phases different from one another. In this embodiment, the phase select signals are set such that the two adjacent data output circuitries select internal clock signals having complementary phases, as shown in FIG. 6.

According to this embodiment, since the transition timings of the output clock signals CLK0_OUT-CLK15_OUT are dispersed during one period, the output timings of the data signals DA0-DA15 outputted from the timing controller 405 are also dispersed. Therefore, the EMI generated in the PCB 410 shown in FIG. 4 can be decreased. Also, by adjusting values of the phase select signals inputted into the selectors in the data output circuitries, it is possible to change the phases of the output clock signals CLK0_OUT-CLK15_OUT. Therefore, it is possible to optimize the output timings of the data signals DA0-DA15 outputted from the timing controller 405 according to an operating environment of the display device.

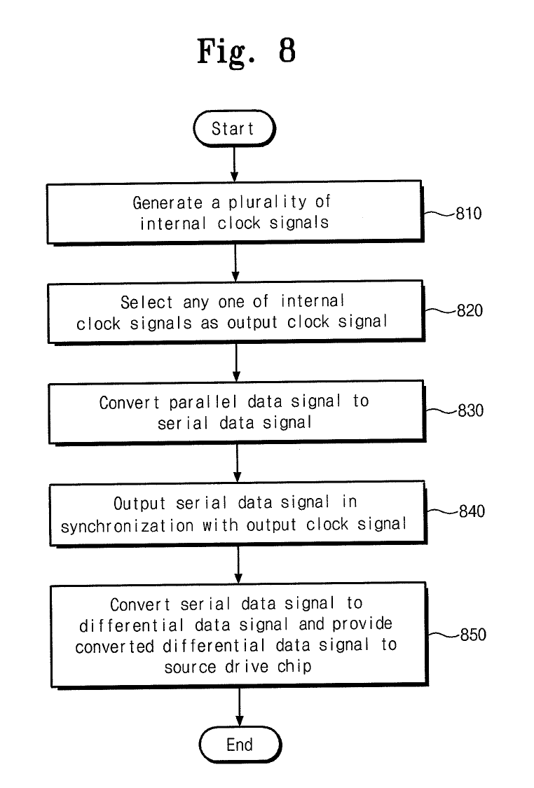

FIG. 8 is a flow diagram illustrating a method of controlling the timing controller shown in FIG. 4 according to an embodiment of the inventive concept.

Referring to FIG. 8, the timing controller 405 generates a plurality of internal clock signals ICLK0-ICLK15 (810). The timing controller 405 selects any one of the internal clock signals ICLK0-ICLK15 as an output clock signal CLK0_OUT (820). The timing controller 405 converts a parallel data signal inputted from a host to a serial data signal DA0_OUT (830). The timing controller 405 outputs the serial data signal DA0_OUT in synchronization with the output clock signal CLK0_OUT (840). The timing controller 405 converts the serial data signal DA0_OUT to a differential data signal DA0 and provides the converted differential data signal DA0 to a source drive chip, e.g., source drive chip 420a (850). If the source drive chip is provided in plurality, the timing controller 405 generates internal clock signals ICLK0-ICLK15 and matches the generated internal clock signals ICLK0-ICLK15 one-to-one with output clock signals CLK0_OUT-CLK15_OUT respectively corresponding to the plurality of drive chips. The timing controller 405 converts data signals provided from the host in synchronization with the output clock signals CLK0_OUT-CLK15_OUT to differential data signals DA0-DA15 and provides the converted data signals DA0-DA15 to the respective source drive chips 420a-420p.

While this embodiment describes the display device as one example of an electronic device, the inventive concept may be applied to other electronic devices in which a signal is transmitted between at least two chips, for example, between a timing controller chip and a source drive chip.

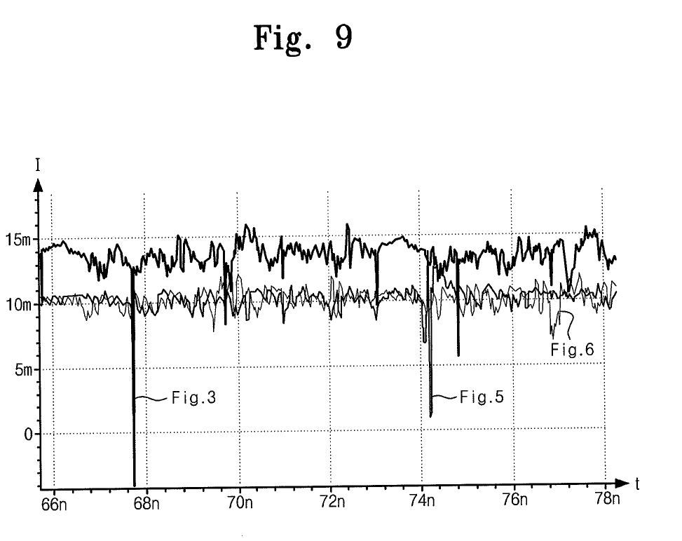

FIG. 9 is a graph illustrating a decrease in current consumed in a display device according to an embodiment of the inventive concept.

Referring to FIG. 9, it can be seen that the current consumed in the display device providing data signals from the timing controller 405 to the source drive chips 420a-420p in synchronization with the output clock signals CLK0_OUT-CLK15_OUT shown in FIG. 6 is less than the current consumed in the display device providing data signals from the timing controller 200 to the source drive chips 141a-141p in synchronization with the clock signals CK0-CK15 shown in FIG. 3. Also, it can be seen that the case of providing data signals from the timing controller 405 to the source drive chips 420a-420p in synchronization with the output clock signals CLK0_OUT-CLK15_OUT shown in FIG. 6 is less in the peak current amount as well as in the total current consumption than the case of providing data signals from the timing controller 405 to the source drive chips 420a-420p in synchronization with the output clock signals CLK0_OUT-CLK15_OUT shown in FIG. 5. It can be expected that the decrease in the peak current amount can decrease EMI generated in a display device.

According to the present disclosure, interference between adjacent data signal lines can be minimized and lowering in the EMI characteristic can be prevented.

The above-disclosed subject matter is to be considered illustrative and not restrictive, and the appended claims are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

What is claimed is:

1. A display device, comprising:
a plurality of source drivers; and
a timing controller generating a plurality of output clock signals corresponding to respective source drivers and providing a data signal to each of the plurality of source drivers in synchronization with the plurality of output clock signals,
wherein the output clock signals have a different phase relative to the output clock signals corresponding to adjacent source drivers among the plurality of source drivers.

2. The display device as claimed in claim 1, wherein the timing controller further provides a clock signal to the plurality of source drivers.

3. The display device as claimed in claim 2, wherein each of the plurality of source drivers recovers the corresponding data signal provided from the timing controller in synchronization with the clock signal.

4. The display device as claimed in claim 3, wherein the data signals and the clock signal provided from the timing controller to the corresponding source drivers are differential signals.

5. The display device as claimed in claim 1, wherein the timing controller includes:
a clock generator generating a plurality of internal clock signals having different phases; and
a plurality of data output circuitries corresponding to respective source drivers of the plurality of source drivers, the data output circuitries selecting any one of the plurality of internal clock signals as the output clock signal, and outputting the data signal to be provided to the corresponding source driver in synchronization with the selected output clock signal.

6. The display device as claimed in claim 5, wherein each of the plurality of data output circuitries includes:
a selector selecting any one of the plurality of internal clock signals as the output clock signal in response to a select signal;
a parallel-to-serial converter converting a parallel data signal inputted from an outside to a serial data signal and outputting the converted serial data signal as the data signal in synchronization with the output clock signal; and
a differential driver converting the data signal to a differential signal and providing the converted differential signal to the corresponding source driver.

7. The display device as claimed in claim 6, wherein the select signal enables the selectors in the respective data output circuitries corresponding to adjacent source drivers to select internal clock signals having predetermined phase differences from the plurality of internal clock signals.

8. The display device as claimed in claim 6, wherein the select signal enables the selectors in the respective data output circuitries corresponding to at least two adjacent source drivers to select internal clock signals having complementary phases from the plurality of internal clock signals.

9. The display device as claimed in claim 1, wherein:
the plurality of source drivers are grouped into a first group of source drivers and a second group of source drivers according to an arrangement of the plurality of source drivers, and
the timing controller provides a first clock signal to the first group of source drivers and a second clock signal to the second group of source drivers, the first clock signal being different from the second clock signal.

10. A display device, comprising:
a plurality of source drivers; and
a timing controller providing a data signal to each of the plurality of source drivers, the timing controller including:
a clock generator generating a plurality of internal clock signals having different phases; and
a plurality of data output circuitries corresponding to respective source drivers, the data output circuitries selecting any one of the plurality of internal clock signals, and outputting the data signal to be provided to the corresponding source driver in synchronization with the selected internal clock signal.

11. The display device as claimed in claim 10, wherein each of the plurality of data output circuitries includes:
a selector selecting any one of the plurality of internal clock signals as an output clock signal in response to a select signal;
a parallel-to-serial converter converting a parallel data signal inputted from an outside to a serial data signal and outputting the converted serial data signal as the data signal in synchronization with the output clock signal; and
a differential driver converting the data signal to a differential signal and providing the converted differential signal to the corresponding source driver.

12. The display device as claimed in claim 11, wherein the select signal enables the selectors in the respective data output circuitries corresponding to adjacent source drivers to select internal clock signals having difference phases from the plurality of internal clock signals.

13. An electronic device, comprising:
a plurality of first semiconductor chips;
a second semiconductor chip generating a plurality of output clock signals corresponding to respective first semiconductor chips and providing a data signal to each of the plurality of first semiconductor chips in synchronization with the plurality of output clock signals; and
a printed circuit board having a plurality of signal lines arranged thereon, the plurality of signal lines transmitting the data signals provided from the second semiconductor chip to the plurality of first semiconductor chips,
wherein the output clock signals have a different phase relative to the output clock signals corresponding to adjacent first semiconductor chips among the plurality of first semiconductor chips.

14. The electronic device as claimed in claim 13, wherein:
the second semiconductor chip further provides a clock signal to the plurality of first semiconductor chips, and
each of the plurality of first semiconductor chips recovers the data signal provided from the second semiconductor chip in synchronization with the clock signal.

15. The electronic device as claimed in claim 14, wherein the second semiconductor chip includes:
a clock generator generating a plurality of internal clock signals having different phases; and
a plurality of data output circuitries corresponding to the respective source drivers of the plurality of source drivers, the data output circuitries selecting any one of the plurality of internal clock signals as the output clock signal, and outputting the data signal to be provided to the corresponding source driver in synchronization with the selected output clock signal.

16. A control method for generating a data signal to be provided to a source driver, the control method comprising:
generating a plurality of internal clock signals having different phases;
selecting any one of the plurality of internal clock signals as an output clock signal;
converting a received parallel data signal to a serial data signal;
outputting the serial data signal as a data signal in synchronization with the selected output clock signal; and
providing the data signal to the source driver.

17. The control method as claimed in claim 16, further comprising converting the data signal to a differential signal, the differential signal being provided to the source driver.

18. A method of controlling a display device for generating a data signal to be provided to a plurality of source drivers, the method of controlling comprising:
generating a plurality of internal clock signals having different phases;
selecting each of the plurality of internal clock signals as output clock signals corresponding to respective source drivers of the plurality of source drivers;
converting parallel data signals corresponding to respective source drivers of the plurality of source drivers to serial data signals;
outputting the serial data signals corresponding to respective source drivers of the plurality of source drivers as data signals in synchronization with the output clock signals corresponding to respective source drivers of the plurality of source drivers; and
providing the data signals to the corresponding source drivers.

19. The method as claimed in claim 18, wherein the selecting of each of the plurality of internal clock signals as the output clock signals includes matching the plurality of internal clock signals with the corresponding source drivers, such that the output clock signals corresponding to adjacent source drivers have different phases.

20. The method as claimed in claim 18, wherein the selecting of each of the plurality of internal clock signals as the output clock signal includes matching the plurality of internal clock signals with the corresponding source drivers, such that the output clock signals corresponding to at least two adjacent source drivers have complementary phases.
